(19) United States
(12) Patent Application Publication
(10) Pub. No.: US 2010/0327699 A1
(43) Pub. Date: Dec. 30, 2010

(54) ENCAPSULATION COATING TO REDUCE PARTICLE SHEDDING

(76) Inventors: Muhammed Hassanali, Shaker Heights, OH (US); Carl Salupo, Berea, OH (US); Steve Keverline, Mentor, OH (US); Fred M. Kimock, Macungie, PA (US)

Correspondence Address: JOHN S. PRATT, ESQ;KILPATRICK STOCKTON, LLP, 1100 PEACHTREE STREET, SUITE 2800, ATLANTA, GA, 30309, US

(21) Appl. No.: 12/865,905

(22) PCT Filed: Feb. 5, 2008
(86) PCT No.: PCT/US08/53031

§ 371 Date: Aug. 3, 2010

(51) Int. Cl. H01L 41/053; C08L 79/08; B05D 5/12

(52) U.S. Cl. 310/340; 524/612; 427/100

(57) ABSTRACT

Various embodiments of the present invention relate to an encapsulated ceramic element coated with polymer material applied precisely to the element edges that are exposed during dicing. Methods of applying the polymer, as well as specific polymers that are particularly useful are disclosed. For example, the polymer material may be applied using precise application methods such as ink-jet printing to direct-write the material precisely where specifically desired. Another method described in the use of photolithographic methods. Additionally, the inventors have identified polyimide as a particularly useful polymer material in connection with certain aspects.

### BACKGROUND OF THE INVENTION

1. Field of the Invention

The present invention relates generally to the field of encapsulation and coatings. In one particular embodiment, certain aspects of this invention are useful as a coating for ceramics, and in even more particular embodiments, as a coating for ceramics used in hard disk drives. Available literature suggests that when the hard disk drives are in operation, particles from the ceramic can break away from the bulk substrate and become mobile inside the disk casing, possibly causing the drive to skip-read or disrupt the fly-height of the reader. Embodiments of this invention help to contain those particles. Other aspects of the invention relate to methods for applying the desired coatings.

2. Description of Related Art

Maintaining cleanliness of parts and assemblies is a major challenge in the disk drive industry. Others have found one challenge is that most disk drive parts are manufactured by conventional manufacturing methods, which often results in particles that are loose or released from the parts and become a primary source of contamination. Disk drive manufacturers generally have effective techniques for ensuring that the drives, as assembled, are cleaned of internal particles. Some articles published about cleaning such components assume that once the components are cleaned and in place, they do not shed particles while in service. While this assumption may hold true for most traditional materials used in hard disk drives, the assumption begins to break down as the variety of materials, especially brittle or friable materials, used for hard disk drives increases. One example of newer materials that may be used are ceramics, such as piezoelectric ceramic materials. Thus, another major challenge for the disk drive industry is controlling particles that are released while the disk drive is in service.

As background, hard disk drive (HDD) systems that employ microactuators use electroactive elements to position the read-head by acting as a “wrist” for the actuator arm. In a suspension-level microactuator, the electroactive elements are typically piezoelectric material (which is typically made of PZT, a solid solution of PbZrO₃ and PbTiO₃ called lead zirconate titanate) attached between a head mounting block (or base plate) of the actuator arm and the head suspension.

Piezoelectric materials (such as PZT ceramics) are useful in applications such as this because they have the ability to convert electrical energy to mechanical energy and vice versa. For example, when a voltage is applied to PZT, it causes the PZT to undergo mechanical deformation, a phenomenon called the converse piezoelectric effect. For PZT to exhibit its piezoelectric properties, however, it is necessary to have good electrical contact between the PZT and the electrode that is used to apply the voltage to the PZT. For this reason, it has been conventional to metallize the top and bottom surfaces of the PZT elements to form electrodes in direct contact with the PZT, while typically leaving the sides bare, so as not to short the ceramic.

The literature implies that in operation, when a voltage is applied to a PZT element, causing it to expand and contract, in order to move the suspension with respect to the actuator arm, the expansion and contraction can cause ceramic particles to be ejected from the PZT element (See, e.g., U.S. Pat. No. 6,930,861). If these particles, which were believed to be generated from both the surfaces and edges of the PZT element, migrate into the space between the slider (which holds the transducing head) and the disk that is rotating at high speed, the disk and the slider can be damaged by interacting with the particles, causing loss of data, damage to the recording head, and head failures.

Efforts to address PZT particle shedding during use have included coating PZT components with resins, epoxies, or plasma sprayed coatings. Exemplary coatings include fluorocarbon polymers (e.g., fluoroacrylate or perfluoropolymer), parylenes, and epoxies. Various coatings may be applied using dip, gravity flow coating, spray coating, spin coating, screen coating, roll coating, or vapor deposition techniques.

In one coating method, a grid is cut into a PZT crystal or ceramic to provide a wide tunnel or space between each PZT element. The grid is what defines each individual PZT element. A coating resin, such as an epoxy, is then flowed into the tunnel between each element and allowed to solidify. Because the tunnel was created larger than typically needed, a cut can be made at the middle of the epoxy-filled tunnel to provide a PZT element that has both sides coated. See, e.g., U.S. Pat. No. 6,393,681.

Another effort to coat PZT elements involves applying an insulating film wound around each PZT element. The film may be an insulating material such as an adhesive-coated resin tape. See, e.g., U.S. Pat. No. 6,661,618. Another example of a coating attempt is to apply a very thin coating around the entire element that can be soldered through, in order to establish an electrical connection with a top electrode. See, e.g., U.S. Pat. No. 6,930,861.

Each of these approaches has drawbacks, however, and the PZT element on suspensions generally remains uncoated. For example, coating materials such as siloxanes can render a PZT element difficult to handle mechanically, rendering its assembly into a disk drive problematic. A PZT element that is encapsulated on all exposed surfaces, including at least one of the metallized regions, requires removing unwanted coating on the metallized regions of the ceramic so that electrodes can be attached, or applying only a very thin coating so that an electrode can be attached despite the coating. Processes of filling voids in a grid with a resin and then machining the resin to separate elements require meticulous machining and risk the creation of flakes of the coating, which are potentially as damaging as ceramic particles are. Accordingly, there remains a need in the art for methods and materials that prevent particle shedding, while allowing ease of handling during the manufacture of disk drives.

### SUMMARY OF THE INVENTION

Embodiments of this invention are based on the premise that the primary regions of particle shedding for ceramic elements (for example, piezoelectric elements and specifically PZT elements) occur not at the metallized regions of the elements, but rather at or close to the element edges, and that these regions can be selectively coated by the process disclosed herein, resulting in an element that can be easily soldered when incorporated into the desired application, for example, a disk drive.

As a result, various embodiments of the present invention relate to a ceramic material, for example a piezoelectric material, such as an encapsulated monolith, a single-layer or single crystal material, a lead-based piezoelectric polycrystalline material, or a multi-layer ceramic material, coated with polymer material applied to the element edges that are exposed during dicing. Many of these materials may be PZT elements and are described herein with respect to PZT elements, but it should be understood that any other ceramics or piezoelectric materials may be used and are considered within the scope of this invention. Generally, any PZT actuating device, whether single or multi-layer, and any ceramic surface is considered for use within the scope of this invention. Examples of potential materials follow, but these are provided for description only, and are not intended to limit the invention in any way.

One example of a single-layer or single crystal material may be a PMN-PT, PZN-PT, or PIN-PT-based solid solution, which may be comprised of (PbA_{y}B_{(1-y)}O₃)₍₁₋ₓ₎—(PbTiO₃)ₓ where A could be Mg, Zn, or In and B is Nb; x is between about 0.25 and 0.60 and y is about between 0.333 and 0.5. An example of a lead-based piezoelectric polycrystalline material may be a polycrystalline ceramic material that includes PbZrO₃—PbTiO₃, PbMg_{1/3}Nb_{2/3}O₃—PbZrO₃—PbTiO₃; PbMg_{1/3}Nb_{2/3}O₃—PbZrO₃—PbTiO₃-based solid solutions.

An example of a multi-layer ceramic material may be a co-fired multilayer, such as a monolithic multilayer actuator comprising a co-fired, sintered stack of thin films of a piezoceramic material with inlaid metallic internal electrodes that project in an alternating manner from the stack end and are electrically connected in parallel by external electrodes. Another multi-layer fabrication could be made from thin sheets of tape-cast ceramic. Silver-palladium electrodes may be deposited on the sheets by screen printing. The sheets are then stacked and co-fired. Co-firing technology helps provide a compact device with high stiffness, low drive voltage, high volumetric efficiency, and fast response time. Lower cost alternative electrode materials for multilayer co-fired ceramics include, but are not limited to, silver-palladium electrodes with a reduced percentage of palladium and copper.

A further embodiment of a multi-layer could be a Multilayer Actuator (MLA), which is a dense, layered structure of co-fired piezoelectric ceramic sheets (typically 5-100 micrometres thick), interleaved with screen printed metallic electrodes. The internal electrodes may have an offset in every other layer (as seen in multilayer capacitors), which creates discrete positive and negative connections on either edge. These internal electrodes may be connected together by an external electrode (thick or thin film), allowing the actuator to be poled and operated with a single connection on either side. Multilayer actuators are most commonly produced as plates (d33) actuators and benders. Multilayer actuators may offer high displacement at lower driving voltages, when compared to bulk piezoelectric equivalents, especially when stacked together.

Methods of applying the polymer, as well as specific polymers that are particularly useful are disclosed. For example, the polymer material may be applied using precise application methods such as ink-jet printing to direct-write the material precisely where specifically desired. In another embodiment of the method of coating the edges of the element, photolithographic methods are used. Additionally, the inventors have identified polyimide as a particularly useful polymer coating material.

Embodiments of this invention provide a method for manufacturing a ceramic element having a polymer coating on specific portions, comprising:
(a) providing a ceramic material mounted on a mounting surface, the ceramic material having a metallized region and being cut to provide one or more cut elements having side walls that are separated by one or more spaces;
(b) using an ink-jet printer to apply a polymer coating to the cut element side walls, leaving the metallized region of the element substantially uncoated.

In some embodiments, the polymer coating is non-conductive. For example, if the material to be coated is a piezoelectric material such as PZT, the polymer coating has to be electrically insulating. In further embodiments, the polymer is applied to the sides of the cut elements by being applied in the spaces between the cut elements. In some embodiments, this application may be conducted at an angle, such that the polymer is applied primarily to the side walls of the cut element only. In other embodiments, the printing is directed straight down, between the cut elements. In even further embodiments, the ink-jet printer comprises a drop-on-demand printer. It may be a continuous-type printer that generates drop sizes or line widths that are at least slightly smaller than the width of the spaces between each cut element. In some embodiments, the polymer is applied to a thickness of up to about three micrometres. In other embodiments, it may be possible for the ink-jet printer to effectively dispense the coating at ambient, low or high temperatures.

The method may also include
(c) allowing the coating to cure;
(d) removing the cut elements from the mounting surface; and
(e) assembling the cut elements in a particle-sensitive environment.
   In some embodiments, the element is cured by one or more of solvent evaporation, cross linking, or UV cure. In some embodiments, the particle sensitive environment is the interior of a hard disk drive. In further embodiments, the polymer may be a liquid polyimide solution.

Other aspects of this invention relate to a method for manufacturing a ceramic element having a polymer coating on specific portions element, comprising:
(a) providing a ceramic material mounted on a mounting surface, the ceramic material having a metallized region and being cut to provide one or more cut elements having side walls that are separated by one or more spaces;
(b) using a photolithographic technique to apply a non-conductive polymer coating to the element; and
(c) applying a developing solution to remove the polymer from the metallized regions of the element, leaving the polymer on the side walls of the cut elements.

Further aspects relate to a use for a liquid polyimide solution, comprising encapsulating the surface of a particle generating part of a ceramic component for use in a hard disk drive.

Even further aspects relate to an encapsulated piezoelectric ceramic, comprising a metallized region and at least one side edge surface, with a layer of polyimide polymer applied as a liquid solution to the at least one side edge surface with an ink-jet printer.

In some embodiments, the ceramic is a single-layer or single crystal material, a lead-based piezoelectric polycrystalline material, a monolayer, a co-fired multilayer, or a PZT material. In other embodiments, the side surfaces are formed by trimming, dicing, or cutting the ceramic to provide sides that are not metallized. In even further embodiments, the coating layer is at or below three micrometres thick.

### BRIEF DESCRIPTION OF THE DRAWINGS

FIG. 1 shows a process flowchart for coating a PZT element

FIG. 2 shows a cross section of a PZT element that is coated using traditional coating methods.

FIG. 3 shows a cross section of a PZT element that is coated using various precision coating methods of this invention.

FIG. 4 shows a schematic of a PZT element having an overflow of coating extending into the spaces between cut elements of the PZT element.

FIG. 5 shows a graph comparing the liquid particle count data for various PZT elements (Formulation I) having different coatings.

FIG. 6 shows a graph comparing the liquid particle count data for various PZT elements (Formulation II) coated using different coating methods.

FIG. 7 shows a SEM micrograph for the vapor-deposited silane-coated PZT element obtained from the coating method of FIG. 6.

FIG. 8 shows a SEM micrograph for the parylene-coated PZT element obtained from the coating method of FIG. 6.

FIG. 9 shows a SEM micrograph for a polyimide-coated PZT element according to one embodiment of the invention.

FIG. 10 shows a micrograph of a parylene-coated PZT element after being picked.

FIG. 11 is a schematic showing a comparison between an unmetallized PZT wafer and a metallized PZT wafer, both having an equal amount of polyimide solution applied thereto.

### DETAILED DESCRIPTION

One object of the various embodiments of the invention is to reduce particle shedding of ceramic components by applying a coating to trap and contain particles that would otherwise dislodge in a particle-sensitive environment (for example, inside a hard disk drive casing, in a biological in vivo application, or in any other appropriate application). Examples of ceramic components include, but are not limited to piezoelectric materials, PZT materials, or any other friable or brittle materials that may experience particle shedding. The coating is applied through precision application methods, such as by using ink-jet technology to apply the coating directly on the desired exposed surfaces of the component, and to only those areas that need the coating. Other methods include the use of photolithographic methods which apply the coating to the entire ceramic element and remove coating from surfaces that are not intended to be coated in the final product. The areas to ultimately be coated are the unmetallized regions of the ceramic elements, particularly the edges or side walls of the elements. The methods described herein also eliminate the need to re-cut the spaces between the cut elements (also referred to in the art as “kerfs”) after the encapsulant has been applied. The resulting ceramic elements reduce particle shedding to levels lower than those currently obtained with other encapsulants, and the methods described herein eliminate the need to ablate, solder, or otherwise re-cut through the coating on the metallized regions.

### Preparing the Element

As described above, piezoelectric materials (such as PZT ceramics, which are specifically discussed in this example, but to which this invention is not limited) are useful in hard disk drives because they have the ability to convert electrical energy to mechanical energy and vice versa. When a voltage is applied to PZT, it undergoes mechanical deformation. For PZT to exhibit its piezoelectrical properties, however, it is necessary to have good electrical contact with the electrode. For this reason, it is necessary to metallize the top and bottom surfaces or regions of the PZT element.

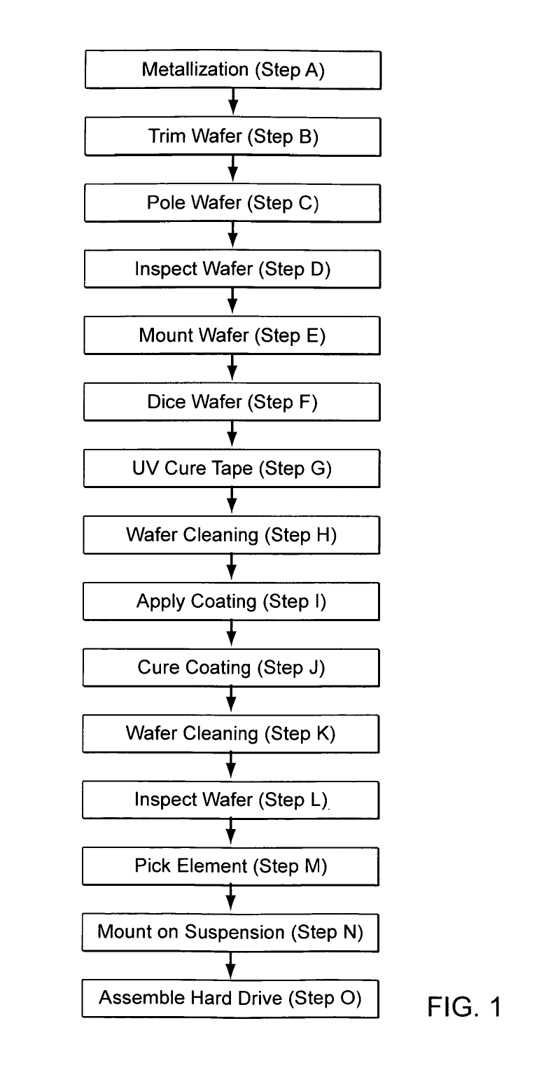

Metallization (the first step “A” shown in FIG. 1) can be achieved through most plating and metallization techniques commonly known in the art. The most common techniques include screen printing, electroplating and electroless plating, vapor deposition, and sputtering. In the metallization process, the edges of the wafer are also metallized, so the edges are typically trimmed, step “B.” After trimming, the wafers are poled (step “C”) by applying a voltage to make the wafer piezoelectric.

Continuing to follow the flowchart of FIG. 1 (which is provided for example only; it should be understood that various steps can be left out or conducted in different orders and still be considered within the scope of this invention), the wafers are then inspected and mounted on wafer carriers for ease of handling. The wafers may be mounted on any appropriate carrier, one example of which is tape that has a UV-curable adhesive on at least one side. Such a carrier may help ease removal of the wafer from the tape, as described in more detail below.

After being mounted, the wafer is cut. The cutting may be accomplished using diamond dicing wheels, although any method is possible and within the scope of this invention. During cutting, the wheel preferably cuts all the way through the wafer and often, partially through the wafer carrier, which may be mounting tape. (While there are several methods for holding a work piece in place, this example uses mounting tape as the wafer carrier to hold the wafer in place during cutting. It should be understood that any other appropriate method is considered within the scope of this invention.) The intent is to cut the material into multiple pieces that have substantially the same dimensions or otherwise provide separate pieces of the wafer material, which will be referred to as “cut elements” or “elements.” It is generally desired that the cut element not be separated from the wafer carrier at this time. The cuts may be any size, and depending upon the thickness of the starting wafer material, a series of cuts (sometimes referred to in the art as “kerfs”) may separate the material into e.g., 24×48 separate cut elements.

The cutting routine may be optimized to provide the best edge quality, while keeping the blade cool and flushing as much of the cutting debris as possible. The spaces that are formed by the cutting may be any desired size, and the resulting cut element may also be any desired size. In some embodiments, the space between cut elements may be between about 25-200 micrometres wide and between about 75-500 micrometres deep. In any event, the depth of the cut is typically the depth of the wafer, such that the wafer is divided into cut elements, but as discussed, the cut preferably does not extend through the wafer carrier.

In specific embodiments, the width of the space may be about 25-100 micrometres wide, and in a more specific embodiment, about 25-80 micrometres wide, and in an even more particular embodiment, about 40 micrometres wide. In other embodiments, the depth of the space may be between about 100-250 micrometres deep, and in a more specific embodiment, about 100-150 micrometres deep, and in an even more particular embodiment, about 125 micrometres deep. Again, the depth of the cut depends upon the thickness (or depth) of the materials. The cut element may range from about 0.5-3 millimetres wide×1.5-5 millimetres long×the depth of the wafer material (e.g., 125 micrometres deep). In a more specific embodiment, the cut element dimensions may range from about 1-3 millimetres wide×2-5 millimetres long×the depth of the wafer material. The above examples are provided for illustration only—they are not intended to limit the invention in any way. These example ranges are provided simply as potential dimensions (lengths, widths, and depths) of the cut elements. It is expected that varying sizes for differing uses can and will be used.

After cutting, if the wafer is mounted on tape with a UV-sensitive adhesive, the tape may be exposed to UV light in order to “cure” the adhesive on the tape to reduce its tackiness. By making the tape less sticky after the cutting process, the adhesion between the tape and the wafer (i.e., the cut element) is reduced, allowing the element to be more easily “picked” from the tape, as described below. The UV exposure may be accomplished using any appropriate method, for example, by applying UV light to the back side of the tape. (The exposure is typically conducted with a machine that also allows UV light to be exposed to the cut element side as well.) Although this step is optional, it has been found that without the UV exposure, the cut element may adhere too well to the tape carrier, and cannot be easily picked. Next, the wafer is cleaned.

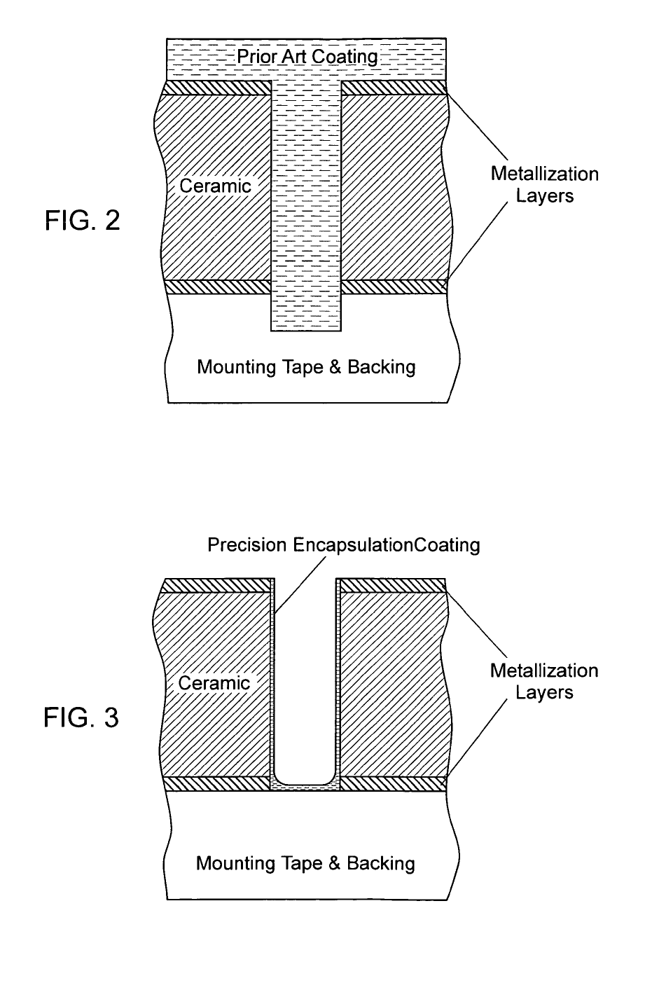

At this point, the traditional PZT elements would now go on to be coated on all exposed sides (i.e., at least five sides). However, for microactuation, it is necessary to maintain electrical contact with the top surface of the PZT element. Thus, for traditional encapsulants that cover all exposed surfaces (including the top surface of the element, as shown in FIG. 2), this means that a sufficient amount of the non-conductive encapsulant would then need to be removed from the top surface to allow for the electrical connection. The present invention, by contrast, provides precision application methods that allow the encapsulant or coating to be applied directly to only those surfaces that need to be encapsulated, as shown in FIG. 3. This thus leaves the metallized top region of the PZT element substantially exposed.

### Ink-Jet Method

One way such precision coating can be accomplished is through the use of an ink-jet printer. In such ink-jet applications, the print-head direct writes inside the spaces (i.e. the areas in between adjacent elements or “cut elements”). This coats the element side walls where bare ceramic is exposed, while leaving the metallized regions uncoated.

Referring back to the flowchart of FIG. 1, the coating steps described fall within step “I.” After cleaning, the wafer is mounted on a print station for ink-jet printing. A number of commercially-available ink-jet printers can be used to apply the encapsulant. Particularly preferred printers include drop-on-demand printers, such as MicroFab's MicroJet II or Litrex's 80L IIJ printers. While the manufacturers of these types of ink-jet printers focus primarily on printing conductive polymers, this application uses the printers to apply all types of polymers, particularly non-conductive polymers. Moreover, these printers have traditionally only been used to print on a flat surface—however, embodiments of this invention use the printers to apply materials to a three-dimensional, sided structure.

Further, instead of printing dots (as is the normal application), this application preferably uses printing lines. (An example of various other ink-jet printers that may be used in accordance with various embodiments of this invention are described in “Cooley et al. Applications of Ink-jet Printing Technology to BioMEMS and Microfludic Systems, Proc. SPIE Conference on Microfludics and BioMEMS, October 2001.”). This ink-jet technology intentionally applies the coating only where it is needed. The polymer thickness may be any appropriate thickness, although it has been found in some cases, that a thickness of less than three micrometres is particularly beneficial. In even more particular embodiments, a coating of between about 0.1-3 micrometres may be provided, and in even more particular embodiments, a coating of between about 0.1-1 micrometre may be used. In some embodiments, it is preferred that the coating be thin in order to prevent twisting or constriction of the element.

Moreover, although the drop-on-demand type printers described above are typically preferred, continuous or continuous-type printers can also be used, as long as the line width is small enough to prevent the encapsulant from flowing out onto the metallized region and the speed of the printer is high enough to prevent the stream of encapsulant drops from accumulating too close together. (Typical continuous printers generate line widths of around 150 micrometres which is likely to be too large for the preferred space size in this application—where space sizes are typically less than 200 micrometres. However, if a continuous printer can generate line widths that would fit the preferred space size at a high enough speed, it may be used.) It is also preferred to use a printer (and specifically an ink-jet printer) that can effectively dispense the coating at various temperatures, such as ambient, low or high temperatures.

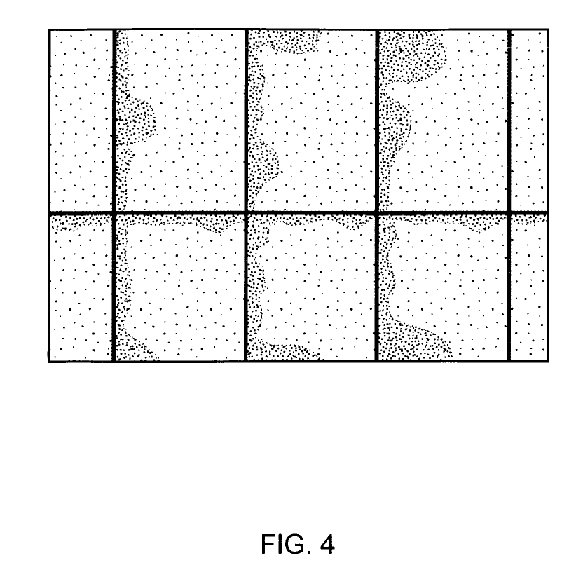

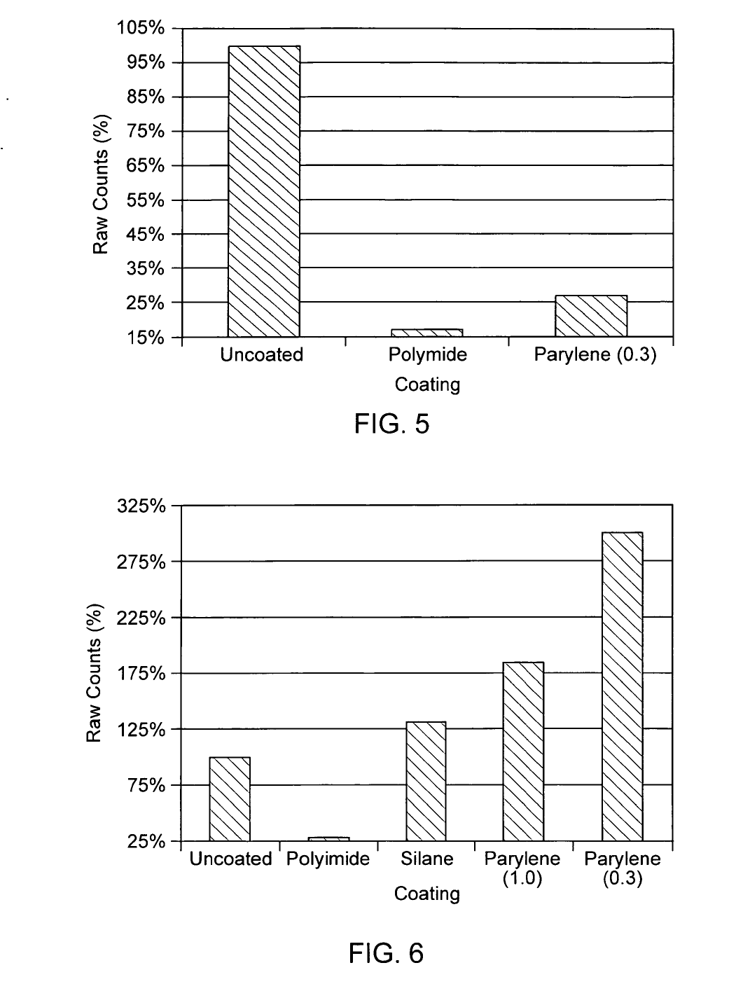

The primary goal of this step is to coat the spaces between the cut elements (and/or the sides of the cut elements) with the desired coating, while leaving the metallized region of the element uncoated. If the drop size or line width is too large, then the coating would overflow to the metallized region, where it is not needed. An example of such an overflow is shown in FIG. 4. (In the trial that formed the sample shown, it is believed that alignment errors may have also contributed to the ink overflow. The polyimide example reflected in FIG. 5 was conducted once the parameters were optimized.) Therefore, for the most desired and effective coating, the droplet size or line width is preferably less than (although it likely needs only to be slightly less than) the space size. In one example, beneficial results were obtained when the droplet diameter or line width was about 68% to 87% of the space size. It is assumed that for similar applications' that droplet sizes or line widths between 55% and 97% of the space size would provide good results.

### Photolithographic Method

An alternate precise application method for use in the coating process is to use a photolithographic method. This consists of globally coating the ceramic element with a compound (such as photo-sensitive polyimide) that alters solubility characteristics upon exposure to specific wavelength radiation. The coating techniques include, but are not limited to spin, spray, or dip methods. Precision exposure can be achieved by using a mask or through maskless methods. A developing solution is then used to remove the compound from the metallized regions, hence leaving the encapsulant on the element edges (e.g., only in the spaces or sides of the cut elements). Both the ink-jet and the photolithographic methods eliminate the need to ablate, solder, or otherwise re-cut through the coating from areas where it is not needed (i.e. from the metallized layer).

After deposition, regardless of which method is used, the wafer is cured as shown in step “J.” Depending upon the encapsulant used, the wafer may be cured using any appropriate method, such as air curing, UV curing, heat curing, and so forth. After curing, the wafer is cleaned (step “K”) to remove any residual contamination from the printing process (generally light surface contamination). After inspection (step “L”), the PZT element now follows the same process path as un-encapsulated wafers would. For example, the elements are picked from the wafer carrier (e.g., tape), mounted on suspension, and assembled in hard drives, or whatever end application is appropriate. One potentially beneficial feature of the coating methods described herein is that no special process is needed to separate the elements from the mounting surface. A typical pick and place machine that is used to remove uncoated die, may also be used with the techniques described herein.

### Polyimide Coating

A second aspect of this invention is the recognition that a polyimide solution is particularly useful as a coating or encapsulant agent for ceramic components in hard disk drive (HDD) applications. The inventors have found that a polyimide solution provides enhanced features and benefits over the other coatings that have been previously used. In a specific embodiment, polyimide in N-methylpyrrolidone (NMP) solution or photo-sensitive polyimide is used. Polyimide can be dissolved in NMP and applied through the precision application methods described above, directly where needed to provide encapsulation. The result is a polyimide polymer coating that is left behind when the solvent evaporates.

Polyimide has not typically been used in hard disk drive (HDD) applications as a coating for ceramic components, but has been used by the biomedical industry because it provides good protection of biomedical devices, is bio-compatible, has good adhesion, is elastically compliant, and can withstand “extreme” conditions (high humidity, large temperature variations, etc). While in this application polyimide is used to reduce particle shedding in hard disk drive applications, it should be understood that polyimide can also be used in other applications (such as biomedical devices) to reduce particle shedding of ceramics used therein. The use of precision application technology allows the use of a liquid coating, so that polymeric coatings (non-limiting examples of which include liquid polyimide, cyanoacrylates, acrylates, epoxies, and novolac) may be used. Although liquid polyimide coatings have been found to work particularly well for this application, it should be understood, however, that there could be other viable coatings that can be used with the above-described application methods that have not been explicitly mentioned in this application, but that are still considered within the scope of the methods of this invention.

With respect to liquid polyimide coatings and without wishing to be bound to any theory, it is believed that polyimide coatings work particularly well in connection with certain aspects of this invention because polyimide is highly polarized. Because PZT ceramics are also highly polarized, it is believed that highly polar solutions or coatings (i.e., materials that have a high dipole moment) have an affinity for wetting the PZT ceramic. For example, a PZT unit cell is cubic and can be thought of as containing lead atoms at the corners of the cube. At the center of each face of the cube is an oxygen atom and either zirconium or titanium at the (body) center of the cube itself. Thus, the PZT structure contains strong dipole moments given the large electron affinity of oxygen (although the entire structure is neutral). Neutral metals (as those in the metallized layer) can be thought of as positive ions immersed in a cloud of electrons. While there are several reasons for coatings to be attracted to a particular substrate, one of these factors is the substrate's electronegativity or dipole moment.

Given the models above for PZT and the metallized layer, it seems likely that coatings that have strong dipoles are more likely to wet PZT than they would be to wet the metallized layer. Strong dipoles in polymers can be achieved through the introduction of oxygen and nitrogen. Carbon and hydrogen have similar electron affinities, and hence do not form a highly electronegative bond. Hydrogen directly bonded to oxygen or nitrogen forms the most polar covalent bonds (resulting in some of the strongest Van der Waal forces).

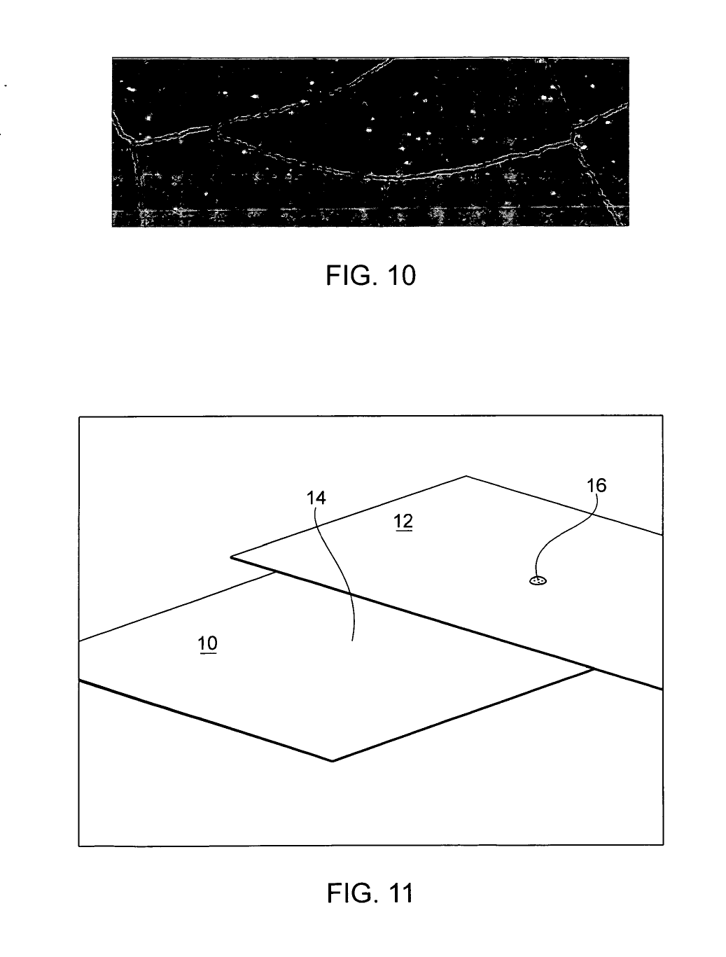

Coatings that have a strong dipole moment and those with a fairly high percentage of oxygen and nitrogen (i.e., those having strong electron donating and electron accepting groups) are more likely to preferentially wet the PZT and “wick” into the micro-crevices and surface irregularities of the PZT substrate. For example, FIG. 11 shows a comparison between the wetting characteristics of an equal amount of polyimide when applied to an unmetallized PZT wafer 10 versus a gold sputter-metallized PZT wafer 12. The thickness of the gold layer is approximately 0.2 micrometre. Specifically, a 20 microliter droplet of polyimide in NMP solution was applied to each wafer surface 10, 12. (This example uses a larger drop size than would be used in a typical application, and is provided only in order to illustrate the differences in wetting.) For perspective, it bears noting that the wafers in FIG. 11 each measured approximately 2″×3″. The droplet of polyimide in NMP was found to have a stronger affinity for the bare, uncoated wafer 10.

As shown, the first droplet of polyimide in NMP 14 wetted the unmetallized surface 10 (the bare, uncoated PZT surface) as shown by the dotted lines circling the area into which it spread out, whereas the second droplet 16 beaded up on the metallized surface or layer 12, as shown by the dotted lines circling the area of the bead. This indicates that the polyimide solution has a natural affinity for the highly polarized PZT ceramic 10, allowing it to wick into the channel edges that are created by the cutting process described herein. Again, it is believed that this activity is due to the polarity of polyimide solution (perhaps in combination with the polarity of the NMP used to dissolve the polyimide), and it is expected that other coatings having a strong dipole moment should behave similarly and may be used according to the methods described herein. (It should be noted that although this experiment was conducted using a relatively large flat surface, the surface that is actually coated in accordance with embodiments of this invention is the space between the cut elements, as shown in FIG. 3. This surface may be smoother or rougher than the flat surface shown in FIG. 11, but nonetheless, the same results are expected to occur.) By contrast, referring back to FIG. 5, a parylene coating that has been vapor deposited on the ceramic (parylene does not have a significant dipole moment, nor is it dissolved in NMP solution as with the polyimide discussed above) is unlikely to penetrate the PZT substrate and is more likely to wet the metallized layer than it is to wet the PZT. Accordingly, it is believed that because of the difference in polarity between parylene and the ceramic, and because the parylene coating was not optimal (e.g., the sides of the element were not specifically coated), the parylene coating flakes easily, an example of which is shown in FIG. 10. Other substances that were used in various experiments were cyanoacrylate and novolac, and it was found that these substances were also less effective at coating the PZT substrate than polyimide. A liquid polyimide solution, on the other hand, due to the nitrogen and oxygen groups in its formulation, is more likely to adhere to the PZT surface than it is to the metallized layer. See FIG. 11. Accordingly, it is believed that polyimide solutions (as well as other coating solutions that have a strong dipole moment) are better candidates for the methods described herein.

Because the precision coating methods described above apply the coating directly in the spaces of adjacent elements—effectively coating the surfaces exposed during dicing—a liquid is often used, although not necessarily required. During the deposition process, polyimide coats the exposed edges as the solvent evaporates. This leaves a conformal coating in the areas where it is needed to provide encapsulation.

### Examples

PZT elements coated with polyimide have been tested and compared to those coated with parylene (and other coatings) and have been found to shed fewer particles. In each case, PZT wafers were attached to mounting tape, then cut into individual PZT elements with a diamond dicing wheel, then ultrasonically cleaned. After drying, the spaces between the cut elements were coated with a liquid polyimide solution using an ink-jet printer as described above while still in position on the mounting tape. After coating, individual PZT elements were removed from the mounting tape and evaluated.

One of the most common methods for measuring cleanliness of hard disk drive components uses liquid particle counts (LPC) of component parts. After the components were cleaned, they were sonicated at ultrasonic frequencies (i.e., ultrasonically cleaned at high power settings close to those where the element would erode in order to “shake off” particles that would otherwise dislodge during normal operation) for a fixed amount of time in a fixed volume of de-ionized water. This is used as a gauge of how clean the ultimate product is. The particles collected in the liquid were then counted through laser scattering. Key parameters that need to be controlled include level of water purity (not only water resistivity, but also level of dissolved gases and other non-ionic impurities), water temperature, etc. In this example, more severe parameters (resulting in higher particle counts) were used due to the large improvement in reducing particle shedding.

The charts shown at FIGS. 5 and 6 show LPC data collected for different coatings applied to PZT elements. In each case, raw counts were normalized to those of an uncoated element (which was set at 100%). The two different charts represent two different formulations of PZT elements that were tested. FIG. 5 shows Formulation I PZT (5H2) and FIG. 6 shows Formulation II PZT (508). Descriptions of the two substrates are included below:

| PROPERTY | | | | |
|---|---|---|---|---|
| NO OF DAYS AFTER POLING | SYMBOL | UNIT | PZT5H2I | PZT508 |
| ELECTRICAL - LOW FIELD | | | | |
| Relative Permittivity | [symbol] ᵣT₃₃ | | 3400 | 3900 |
| Relative Permittivity | [symbol] ᵣT₁₁ | | — | — |
| Dielectric Loss | Tan δ | | 0.025 | 0.02 |
| Resistivity (at 25°) | ρ ∈l | Ωm | >10 [symbol] | |
| Resistivity (at 100°) | ρ ∈l | Ωm | 10 [symbol] | — |
| Resistivity (at 200°) | ρ ∈l | Ωm | 10 [symbol] | — |
| ELECTRICAL - HIGH FIELD | | | | |
| Increase in [symbol] ᵣT₃₃ @ 2 KV/cm | | % | — | — |
| Dielectric Loss @ 2 KV/cm | Tan δ | | — | — |
| Increase in [symbol] ᵣT₃₃ @ 4 KV/cm | | % | — | — |
| Dielectric Loss @ 4 KV/cm | Tan δ | | — | — |
| ELECTRO-MECHANICAL | | | | |
| Coupling Factors | kₚ | | 0.65 | 0.71 |
| | k₁₅ | | 0.68 | 0.72 |
| | k₃₁ | | −0.39 | 0.41 |
| | k₃₃ | | 0.75 | −0.75 |
| | kₜ | | — | — |
| Charge Constants | d₃₃ | ×10 [symbol] C/N | 593 | 720 |
| or Strain Constants | d₃₁ | ×10 [symbol] C/N or m/V | −274 | −315 |
| | d [symbol] | ×10 [symbol] C/N | 45 | 90 |
| | d₁₅ | ×10 [symbol] C/N or m/V | 741 | 750 |
| Voltage Constants | g₃₃ | ×10 [symbol] Vm/N | 19.7 | 18.5 |
| or Stress Constants | g₃₁ | ×10 [symbol] Vm/N | −9.1 | −9 |
| | g [symbol] | ×10 [symbol] Vm/N | 1.5 | 0.5 |
| | g₁₅ | ×10 [symbol] Vm/N | 26.8 | — |
| | d [symbol] | ×10 [symbol] | 68 | 45 |
| Frequency Constants | N [symbol] | Hz · m | 1965 | 1950 |
| | N [symbol] ₁ | Hz · m | 1420 | 1420 |
| | N [symbol] ₃ | Hz · m | — | 1880 |
| | N [symbol] | Hz · m | 1930 | — |
| | N₃₁ or N₃₃ | Hz · m | 2000 | — |
| | N [symbol] | Hz · m | — | — |
| | Hoop or N [symbol] | Hz · m | 890 | — |
| | Nₜ | Hz · m | — | — |
| Compressive Strength | | 10 [symbol] Pa | — | — |
| Tensile Strength | | 10 [symbol] Pa | — | — |
| Quality Factor | Qₘ | | 65 | — |
| | | | | 55 |
| MECHANICAL | | | | |
| Compliances | S [symbol] | ×10 [symbol] m [symbol] /N | 20.8 | 22 |
| | S [symbol] ₁₁ | ×10 [symbol] m [symbol] /N | 16.4 | 16.4 |
| | S [symbol] ₁₂ | ×10 [symbol] m [symbol] /N | — | — |
| | S [symbol] ₁₃ | ×10 [symbol] m [symbol] /N | — | — |
| | S [symbol] | ×10 [symbol] m [symbol] /N | — | — |
| | S [symbol] | ×10 [symbol] m [symbol] /N | — | — |
| | S [symbol] ₃₃ | ×10 [symbol] m [symbol] /N | 9 | 8.8 |
| | S [symbol] ₁₁ | ×10 [symbol] m [symbol] /N | 14.1 | 13.9 |
| | S [symbol] ₁₂ | ×10 [symbol] m [symbol] /N | — | — |
| | S [symbol] | ×10 [symbol] m [symbol] /N | — | — |
| | Y [symbol] ₃₃ | ×10 [symbol] N/m [symbol] | 4.8 | 4.9 |
| | Y [symbol] ₁₁ | ×10 [symbol] N/m [symbol] | 6.2 | 6.1 |
| | Y [symbol] ₃₃ | ×10 [symbol] N/m [symbol] | 11.1 | 11 |
| | Y [symbol] ₁₁ | ×10 [symbol] N/m [symbol] | 7.1 | 7 |
| Poisson's Ratio [symbol] | | | — | — |
| Density | ρ | kg/m [symbol] | 7450 | 7900 |
| THERMAL DATA | | | | |
| Curie Temperature | T_{c} | ° C. | 195 | 220 |
| Approx. Operating Temp. | | ° C. | 110 | — |
| Specific Heat | | [symbol] /kg K | — | — |
| Thermal Conductivity | | W/m K | — | — |
| Young's Modulus | E | Gpa | — | — |
| Internal Friction | Q [symbol] | ×10 [symbol] | — | — |
| TIME STABILITY | | Relative change per | | |
| Coupling Factor | k [symbol] | time decade % | −0.20 | — |
| Capacitance | C | | — | — |
| Permittivity | [symbol] T₃₃ | | −0.60 | — |
| Frequency | f | | — | — |
| | d₃₃ | | −3.90 | — |
| Time Constant | | Seconds | — | — |
| | N [symbol] | | +0.3 | — |

[symbol]

indicates data missing or illegible when filed

In this example, both formulations are different formulations of PZT-5 and are considered high sensitivity soft materials. Thus, it is expected that similar results would be obtained for other ceramic formulations including soft or hard PZT.

As shown in FIG. 5, the following types of coatings were tested: ink jet applied polyimide and vapor-deposited parylene (thickness 0.3 micrometer). As shown in FIG. 6, the following types of coatings were tested: ink jet applied polyimide, vapor-deposited silane, vapor deposited parylene at thicknesses of 1 micrometer and 0.3 micrometer.

Testing with Polyimide

Generally, it was found that polyimide coatings are superior to the other coatings tested. The parameters used to obtain superior results with polyimide coating are listed below, but it should be understood that these are examples of potential parameters only and other parameters may be used to optimize results:
Polyimide from Nissan Chemical, Electronics Material Division (grade: 7492, Type: 062M, Lot #: 4J21 LT)
Solvent: NMP (6% polyimide (“PI”))
MicroFab printer (table moves while the head is stationary)
Voltage: 65V
Pulse Width: 6.5 microseconds
Slope: 40/40 V/microseconds
Drop Volume: 30 pL nominal
Drop Frequency: 42 drops/millimetre
Printing Speed: 32 millimetres/second
Nozzle size—25-30 micrometres
Number of Passes: 1

Printing was conducted with 6% polyimide (PI) in NMP solution. The rise time and fall time (useful if printing higher viscosity material) can be set independently, and optimal settings are based on the ink's viscosity, nozzle, and ink wetting characteristics. For example:

As a drop leaves the printer orifice, a tail is formed. Ideally, the tail should “snap” back into the drop. If it goes back into the orifice, then the drop size is smaller than expected, and there is a possibility of build-up on the orifice. Sometimes, however, when the tail “snaps,” it forms a satellite drop. Satellite drops may cause uneven coverage of the substrate. Accordingly, reducing the time to go from maximum voltage to zero, or using a negative voltage typically solves the problem of satellite drops. In addition, an echo dwell time can be set allowing the transducer to pull back any (small) satellites. In this example, the rise and fall times were set to 3 microseconds, which will vary from printer to printer.

Before printing directly on PZT, it may be desirable to run a test run on the mounting tape to make sure that there is enough overlap between adjacent drops. Print-head speed and dispense frequency may be adjusted until substantially uniform lines of polyimide solution are obtained. However, as the PZT and tape wet differently, dispensing on the surface of the cut element can also be beneficial in order to visually observe effects on the PZT surface in order to further optimize parameters as need be.

To ensure that the appropriate spaces are printed, the printing may be started before the saw cuts (on the mounting tape), and ended after the cuts on the other side of the tape. Preferably, a complete row or column is printed. The space between the elements can then be checked to ensure that the polyimide solution is printed inside the space or whether realignment is needed. In this experiment, instances when the space was “missed” or alignment was otherwise not perfect or precise, the overflow was not significant enough to cause concerns. If the printer clogs, it has been found that back flushing the transducer with NMP, and ultrasonically cleaning and rinsing it in acetone can be effective.

In one embodiment, during the jetting process, the entire space between the cut elements may be filled. During cure, the solvents evaporate leaving the polyimide polymer solids behind. These solids then adhere to the cut element side walls and the mounting surface (e.g., tape). As the polyimide solution wetting angle to the tape is high, most of the polyimide solution migrates to the bare PZT surface. It is believed that this migration into the surface provides the desired optimal encapsulation.

Testing with Other Coatings

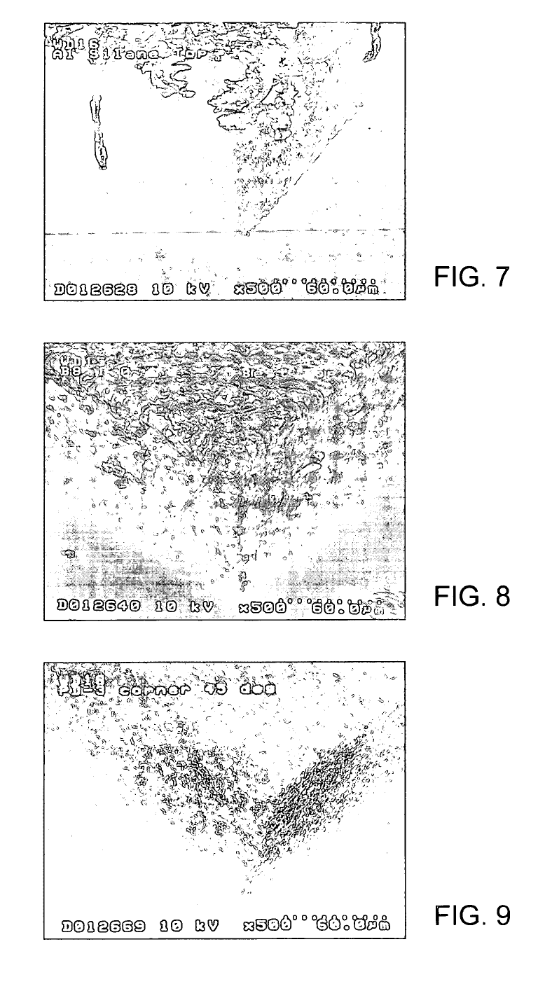

As shown in FIG. 6, the present inventors have found that coatings of silane and parylene increased particle shedding (as compared to an uncoated sample). By contrast, a polyimide coating greatly reduced particle shedding. To understand why particle shedding increased with these other coatings, SEM pictures of some coated sample elements representative of those used in the tests conducted in FIG. 6 were taken, and are shown in FIGS. 7, 8, and 9. FIG. 7 shows an element that was coated with a vapor-deposited silane treatment, in which the silane coating formed and remained on top of the element, but is not apparent on the cut sides of the element, or hardly penetrated into the spaces between individual elements. This could be because the non-metallized PZT surface does not adequately wet with silanes, or because the vapor flux was blocked from the sides of the element by shadowing from an adjacent element on the mounting tape. The element in FIG. 8 was coated with parylene. Parylene is known to have poor adhesion to most surfaces. In this case, the parylene may simply be flaking off during ultrasonic treatment, resulting in high LPC counts. The element in FIG. 9 is coated with polyimide according to embodiments of the invention. Because the coating is only applied in the spaces between the elements, it is only found on the unmetallized vertical side walls of the element. The polyimide coating in this example is very thin (less than 0.3 micrometre per Auger depth profiling measurement) and conformal to the vertical side walls of the element. It is generally believed that the optimum coating thickness is less than about three micrometres.

Another parameter that should be considered when manufacturing a PZT element is pickability (i.e. whether the element can be picked up by mechanical means without cracking). Attempts to pick up a parylene-coated element of the type shown in FIG. 8 proved difficult due to breakage, making the parylene-coated elements unsuitable for micro-actuation, as shown in FIG. 10.

As previously mentioned, PZT is only useful in its applications if it can retain its piezoelectric properties. A complete coating on all sides of a PZT element restricts mechanical deformation and causes clamping. To ensure that there is no clamping with PZT elements manufactured according to various embodiments of the invention, electrical measurements were conducted on PZT elements printed with polyimide solution versus uncoated elements. Performance parameters (such as d₃₁) were compared statistically. It was found that elements coated with polyimide solution using the coating methods and materials described herein were not statistically different in their performance from those that were uncoated. This series of tests confirms that the coating methods and materials of this invention can be used for microactuation in hard disk drive applications, and that they are a superior solution compared to using an uncoated element.

Once the elements are prepared, coated and cured, they may be removed from the mounting surface and assembled in a particle-sensitive environment, such as the interior of a hard disk drive. Each cut element may be individually bonded to the suspension.

Changes and modifications, additions and deletions may be made to the structures and methods recited above and shown in the drawings without departing from the scope or spirit of the invention and the following claims.

1. A method for manufacturing a ceramic element having a polymer coating on specific portions, comprising:
(a) providing a ceramic material mounted on a mounting surface, the ceramic material having a metallized region and being cut to provide one or more cut elements having side walls that are separated by one or more spaces;
(b) using an ink-jet printer to apply a polymer coating to the cut element side walls, leaving the metallized region of the element substantially uncoated.

2. The method of claim 1, wherein the polymer coating is non-conductive.

3. The method of claim 1, wherein the polymer is applied in liquid form.

4. The method of claim 3, wherein the polymer is a liquid polyimide solution.

5. The method of claim 1, wherein the polymer has a high dipole moment.

6. The method of claim 1, wherein the polymer is a polymer that has a greater tendency to wet the piezoelectric material than the metallized region.

7. The method of claim 1, wherein the polymer is applied to the sides of the cut elements by being applied in the spaces between the cut elements.

8. The method of claim 1, wherein the ink-jet printer comprises a drop-on-demand printer.

9. The method of claim 1, wherein the ink-jet printer comprises a continuous printer that generates line widths that are at least slightly smaller than the width of the spaces between the cut elements.

10. The method of claim 1, wherein the polymer is applied to a thickness of up to about three micrometres.

11. The method of claim 1, wherein the ink-jet printer can effectively dispense the coating at ambient, low, or high temperatures.

12. The method of claim 1, further comprising
(c) allowing the coating to cure;
(d) removing the cut elements from the mounting surface; and
(e) assembling the cut elements in a particle-sensitive environment.

13. The method of claim 12, wherein the element is cured by one or more of solvent evaporation, cross linking, or UV cure.

14. The method of claim 12, wherein the particle sensitive environment is the interior of a hard disk drive.

15. The method of claim 1, wherein the ceramic comprises a piezoelectric transducer element, a single-layer or single crystal material, a lead-based piezoelectric polycrystalline material, a monolayer, or a co-fired multilayer.

16. A method for manufacturing a ceramic element having a polymer coating on specific portions, comprising:
(a) providing a ceramic material mounted on a mounting surface, the ceramic material having a metallized region and being cut to provide one or more cut elements having side walls that are separated by one or more spaces;
(b) using a photolithographic technique to apply a non-conductive polymer coating to the element; and
(c) applying a developing solution to remove the polymer from the metallized regions of the element, leaving the polymer on the side walls of the cut elements.

17. The method of claim 16, wherein the ceramic comprises a piezoelectric transducer element, a single-layer or single crystal material, a lead-based piezoelectric polycrystalline material, a monolayer, or a co-fired multilayer.

18. A use for a liquid polyimide solution, comprising: encapsulating the surface of a particle generating part of a ceramic component for use in a hard disk drive.

19. An encapsulated piezoelectric ceramic, comprising a metallized region and at least one side edge surface, with a layer of polyimide polymer applied as a liquid solution to the at least one side edge surface with an ink-jet printer.

20. The piezoelectric ceramic of claim 19, wherein the ceramic comprises a single-layer or single crystal material, a lead-based piezoelectric polycrystalline material, a monolayer, a co-fired multilayer, or a PZT material.

21. The piezoelectric ceramic of claim 19, wherein the side surfaces are formed by trimming or dicing the ceramic to provide sides that are not metallized.

22. The piezoelectric ceramic of claim 19, wherein the coating layer is at or below three micrometres thick.

23. A hard disk drive incorporating an encapsulated piezoelectric made by the method of claim 1.

24. A hard disk drive incorporating an encapsulated piezoelectric made by the method of claim 16.

25. A hard disk drive incorporating an encapsulated piezoelectric as claimed in claim 19.
